(19) United States
(12) Patent Application Publication
(10) Pub. No.: US 2014/0158181 A1
(43) Pub. Date: Jun. 12, 2014

(54) SOLAR RADIATION FILTER AND ELECTRIC POWER GENERATOR

(71) Applicant: QUALCOMM MEMS TECHNOLOGIES, INC., San Diego, CA (US)

(72) Inventor: Igor Tchertkov, San Jose, CA (US)

(73) Assignee: QUALCOMM MEMS Technologies, Inc., San Diego, CA (US)

(21) Appl. No.: 13/708,429

(22) Filed: Dec. 7, 2012

(51) Int. Cl. H01L 31/052; H01L 31/18

(52) U.S. Cl. CPC H01L 31/0522; H01L 31/18
USPC 136/246; 29/592.1

(57) ABSTRACT

This disclosure provides systems, methods and apparatus including a power generating and a power saving device having a plurality of shutters and a plurality of photovoltaic (PV) devices. In one aspect, each of the plurality of shutters is configured to move laterally in the plane of the shutter by the action of one or more electrostatic actuators. The array of shutters can control the amount of ambient light that is transmitted through the device. Additionally, the array of shutters can shield or expose the array of the PV devices to ambient sunlight to generate PV power.

### TECHNICAL FIELD

This disclosure relates to the field of photovoltaic power generating devices and more particularly to smart glass panels that can vary the amount of radiation that is transmitted through and generate photovoltaic power.

### DESCRIPTION OF THE RELATED TECHNOLOGY

Solar energy is a renewable source of energy that can be converted into other forms of energy such as heat and electricity. Some drawbacks in using solar energy as a reliable source of renewable energy are low efficiency in collecting solar energy, in converting light energy to heat or electricity and the variation in the solar energy depending on the time of the day and the month of the year.

A photovoltaic (PV) cell can be used to convert solar energy to electrical energy. Systems using PV cells can have conversion efficiencies between 10-20%. PV cells can be made very thin and are not big and bulky as other devices that use solar energy. For example, PV cells can range in width and length from a few millimeters to 10's of centimeters. Although, the electrical output from an individual PV cell may range from a few milliwatts to a few watts, due to their compact size, several PV cells may be connected electrically and packaged to produce a sufficient amount of electricity. For example, a solar panel including a plurality of PV cells can be used to produce sufficient amount of electricity to satisfy the power needs of a home.

Solar concentrators can be used to collect and focus solar energy to achieve higher conversion efficiency in PV cells. For example, parabolic mirrors can be used to collect and focus light on PV cells. Other types of lenses and mirrors can also be used to collect and focus light on PV cells. These devices can increase the light collection efficiency. But such systems tend to be bulky and heavy because the lenses and mirrors that are required to efficiently collect and focus sunlight can be large.

Accordingly, for many applications such as, for example, providing electricity to residential and commercial properties, charging automobile batteries and other navigation instruments, it is desirable that the light collectors and/or concentrators are compact in size.

PV materials are also increasingly replacing conventional building materials in parts of the building envelope such as windows, roofs, skylight or façades. PV materials incorporated in building envelopes can function as principal or secondary sources of electrical power and help in achieving zero-energy buildings. One of the currently available building-integrated photovoltaic (BIPV) products is a crystalline Si BIPV, which is made of an array of opaque crystalline Si cells sandwiched between two glass panels. Another available BIPV product is a thin film BIPV which is manufactured by blanket depositing PV film on a substrate and laser scribing of the deposited PV film from certain areas to leave some empty spaces and improve transmission. However, such products may suffer from low transmission (5-20%), disruptive appearance and serious artifacts. Additionally, a thin film BIPV may also be expensive to manufacture.

Accordingly, BIPV systems that can efficiently generate electrical power and reduce manufacturing costs are desirable.

### SUMMARY

The systems, methods and devices of the disclosure each have several innovative aspects, no single one of which is solely responsible for the desirable attributes disclosed herein.

One innovative aspect of the subject matter described in this disclosure can be implemented in a power generating and power saving device including a transmissive panel, an array of shutters, and an array of PV devices. In some implementations, the transmissive panel has a forward surface for receiving ambient light and a rearward surface opposite the forward surface. The array of shutters is disposed closer to the forward surface of the panel. Each shutter may include a layer of photovoltaic (PV) material disposed facing the forward surface of the panel. Each shutter in the array is adapted to move between an open state and a closed state. The array of PV devices may be disposed rearward of the array of shutters. The array of shutters and the array of photovoltaic devices are structured in shape and/or size such that in the open state a first portion of the received ambient light is transmitted through the rearward surface of the substrate and a second portion of the received ambient light is incident on the layer of PV material on the shutters. The array of shutters and the array of photovoltaic devices are structured in shape and/or size such that in the closed state a first portion of the received ambient light is incident on the layer of PV material on the shutters and a second portion of the received ambient light is incident on the array of PV devices. In various implementations, the array of PV devices can include a thin film photovoltaic cell

In various implementations, the power generating and power saving device is configured such that in the open state the first portion can be between approximately 30% and approximately 50% of the received ambient light. In some implementations, the device can be configured such that in the open state the second portion can be between approximately 10% and approximately 50% of the received ambient light. In some implementations, in the closed state the first portion can be between approximately 5% and approximately 50% of the received ambient light. In various implementations, in the closed state a second portion can be between approximately 30% and approximately 50% of the received ambient light. In some implementations, in the open state each shutter can be aligned with a corresponding PV device from the array of PV devices such that less than 10% of the received ambient light is directly incident on the array of PV devices. In various implementations, in the closed state each shutter can be offset with respect to a corresponding PV device from the array of PV devices such that the second portion of the received ambient light is directly incident on the PV devices.

In some implementations of the device, the panel can include a first transmissive substrate having a forward and a rearward surface and the array of shutters can be disposed closer to the rearward surface of the first substrate. In some implementations, the panel can include a second transmissive substrate having a forward and a rearward surface and the array of PV devices is disposed over the forward surface of the second substrate facing the array of shutters.

In various implementations, some of the array of shutters can include a mechanical shutter that is configured to move laterally in a plane parallel to the forward surface of the panel between the open state and the closed state. The mechanical shutter can be moved between the open state and the closed state by one or more electro-static actuators. The mechanical shutter can be suspended from one or more support structures. In various implementations, the support structure can be configured as a mechanical spring. In some implementations, the support structure can be configured as an electrode of an electro-static actuator that is adapted to slide the mechanical shutter.

Various implementations of the device can be configured as a window and/or as a skylight.

Another innovative aspect of the subject matter described in this disclosure can be implemented in a power generating and power saving device including a transmissive panel, a plurality of means for blocking light; and an array of PV devices. The transmissive panel has a forward surface for receiving ambient light and a rearward surface opposite the forward surface. The plurality of means for blocking light is disposed closer to the forward surface of the panel. Each light blocking means includes a layer of photovoltaic (PV) material disposed facing the forward surface of the panel. Each light blocking means is adapted to move between an open state and a closed state. The array of PV devices is disposed rearward of the plurality of light blocking means. The plurality of light blocking means and the array of photovoltaic devices are structured in shape and/or size such that in the open state a first portion of the received ambient light is transmitted through the rearward surface of the panel and a second portion of the received ambient light is incident on the layer of PV material on the light blocking means. The plurality of light blocking means and the array of photovoltaic devices are structured in shape and/or size such that in the closed state a first portion of the received ambient light is transmitted through the rearward surface of the panel and a second portion of the received ambient light is incident on the array of photovoltaic devices.

In various implementations, the plurality of light blocking means can include a mechanical shutter. In some implementations, the plurality of light blocking means can be configured to move laterally in a plane parallel to the forward surface of the panel between the open state and the closed state. In various implementations, the plurality of light blocking means can be moved between the open state and the closed state by one or more electro-static actuators.

Another innovative aspect of the subject matter described in this disclosure can be implemented in a method of manufacturing a power generating device. The method includes providing a transmissive panel having a forward surface for receiving ambient light and a rearward surface opposite the forward surface. The method further comprises disposing an array of shutters disposed closer to the forward surface of the panel and disposing an array of PV devices disposed rearward of the array of shutters. Each shutter may includes a layer of PV material that is disposed facing the forward surface of the panel. Each shutter in the array is adapted to move between an open state and a closed state. The array of shutters and the array of PV devices may be are structured in shape and/or size such that in the open state a first portion of the received ambient light is transmitted through the rearward surface of the panel and a second portion of the received ambient light is incident on the layer of PV material on the shutters. The array of shutters and the array of PV devices may be structured in shape and/or size such that in the closed state a first portion of the received ambient light is transmitted through the rearward surface of the panel and a second portion of the received ambient light is incident on the array of PV devices.

In various implementations, some of the array of shutters can include a mechanical shutter that is configured to move laterally in a plane parallel to the forward surface of the panel between the open state and the closed state. In various implementations, the mechanical shutter can be suspended from one or more support structures. In some implementations, the method further comprises providing an electro-static actuator including the support structure. The electro-static actuator can be adapted to move the mechanical shutter between the open state and the closed state.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Example implementations disclosed herein are illustrated in the accompanying schematic drawings, which are for illustrative purposes only.

FIGS. 1A and 1B illustrate an implementation of a panel 100 including an array of shutters, each shutter configured to move laterally in a plane in which the shutter is aligned between an open state and a closed state.

FIGS. 1C and 1D illustrate an implementation of a PV power generating panel (for example, the panels depicted in FIGS. 1A and 1B) and an array of PV devices.

FIGS. 2A and 2B illustrate a plan view of an implementation of an array of microelectromechanical systems (MEMs) based shutters 220 that are electrostatically actuated to move laterally in a plane in which the shutters are aligned between an open state and a closed state.

FIG. 2C illustrates a side view of an implementation of a PV power generating panel including the MEMs based shutter depicted in FIGS. 2A and 2B.

FIG. 3 is a flow chart 300 illustrating an example of a method of manufacturing an implementation of a power generating device including an array of shutters and PV devices.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. As will be apparent from the following description, the innovative aspects may be implemented in any device or object that is configured to generate PV power, filter solar radiation, and/or control the amount of solar radiation transmitted. More particularly, it is contemplated that the innovative aspects may be implemented in or associated with a variety of applications such as providing power to residential and commercial structures and properties, providing power to electronic devices such as laptops, personal digital assistants (PDA's), wrist watches, calculators, cell phones, camcorders, still and video cameras, MP3 players, etc. Some of the implementations, described herein can be used in BIPV products such as windows, roofs, skylight or façades. In addition the implementations described herein can be used in wearable power generating clothing, shoes and accessories. Some of the implementations described herein can be used to charge automobile batteries or navigational instruments and to pump water. The implementations described herein can also find use in aerospace and satellite applications. Other uses are also possible.

As discussed more fully below, various implementations described herein, include a device having an array of light impeding structures (which will be referred to herein as “shutters”) that can be controlled to move between an open state and a closed state to vary the amount of light transmitted. In various implementations, the shutters can include a microelectromechanical systems based device that can be electrostatically actuated to move laterally, for example, move in a plane in which one or more shutters are aligned, between the open state and the closed state. In other implementations, the device includes a fixed array of PV cells which are shielded from or exposed to light when the shutters are moved between an open state and a closed state. In various implementations, some or all the shutters in the array can include PV material on the portion that receives incident light to generate PV power. The amount of light transmitted through the device can be varied between a maximum amount and a minimum amount. The maximum and minimum amount of light transmitted through the device can depend on the size, position, density and shape of the shutters and other structure of the device (for example, apertures). In various implementations, the amount of light transmitted through the device can vary between approximately 0 and 50% of the amount of light incident on the device.

Particular implementations of the subject matter described in this disclosure can be implemented to realize one or more of the following potential advantages. The implementations described herein can be integrated in architectural structures such as, for example, windows, roof, skylights, or façades to electronically control the amount of incident light that is transmitted and to generate PV power. In such examples, the device functions as mini/micro-blinds that can be electrically controlled and generate PV power. Additionally, various implementations of the device described herein can be used to filter incident UV/IR radiation to prevent heating of the interior of the architectural structures due to radiation.

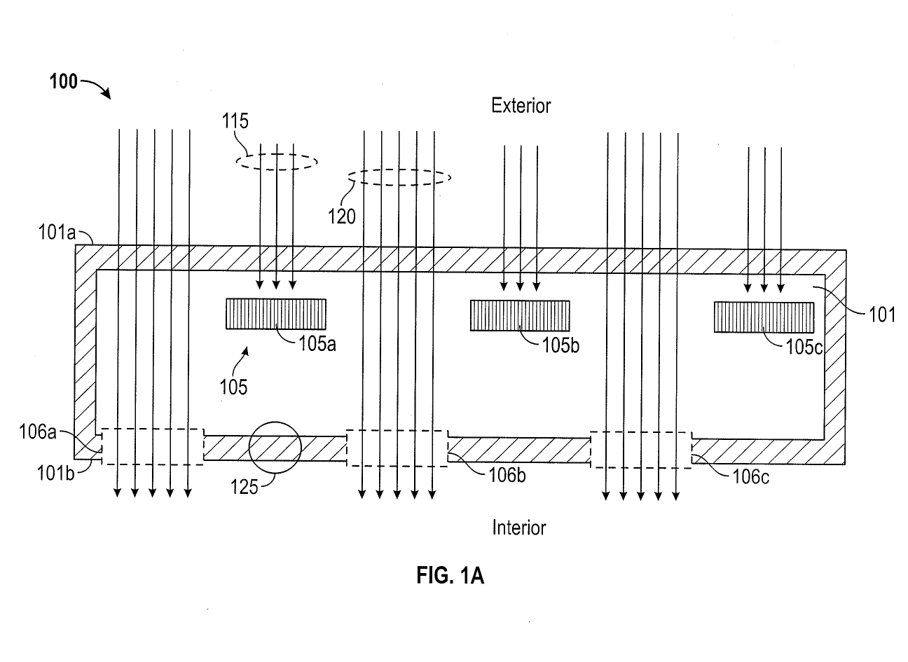

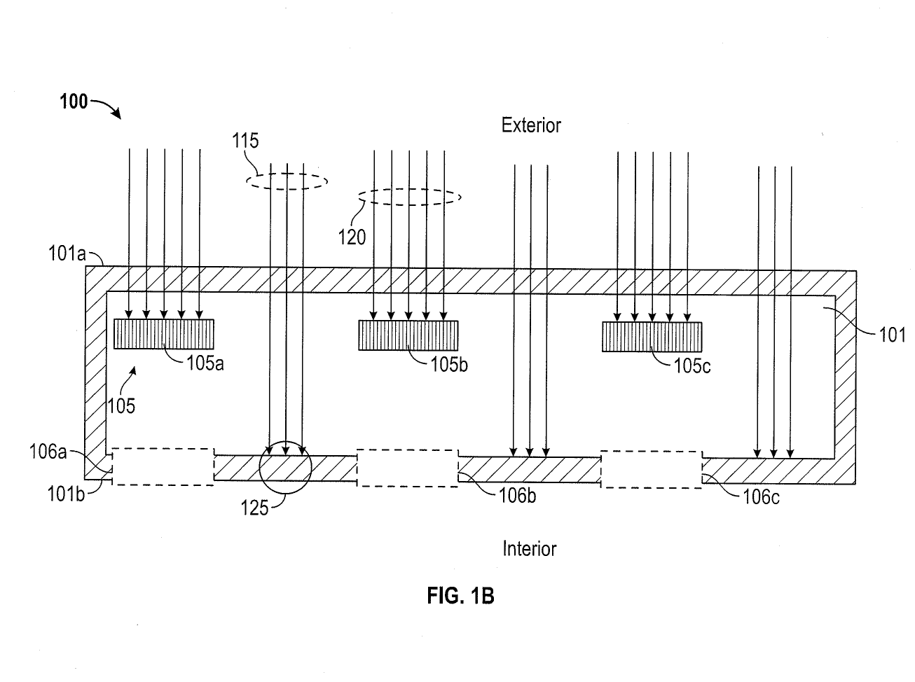

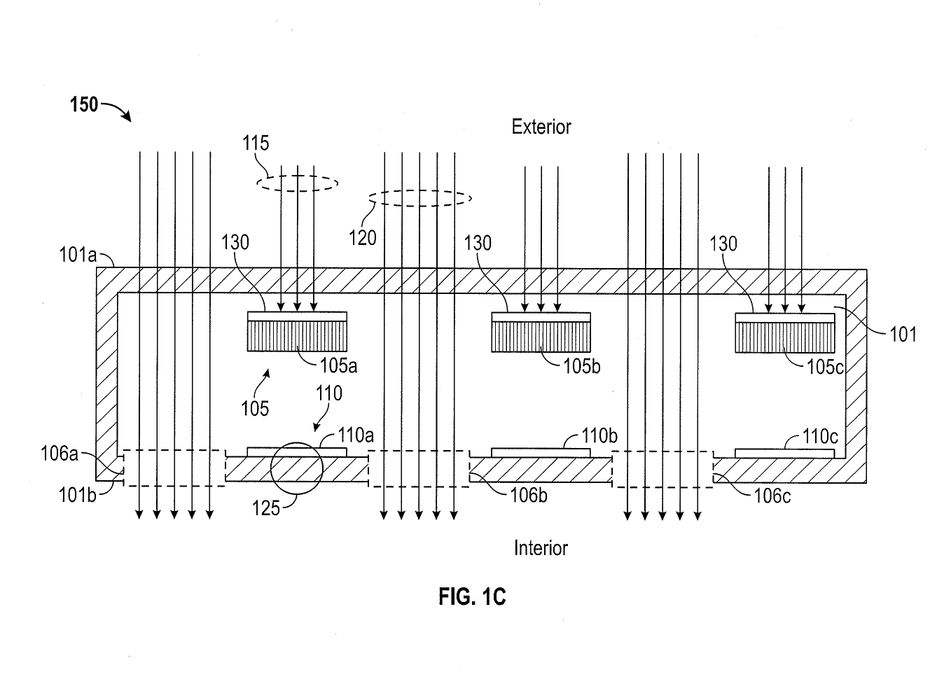

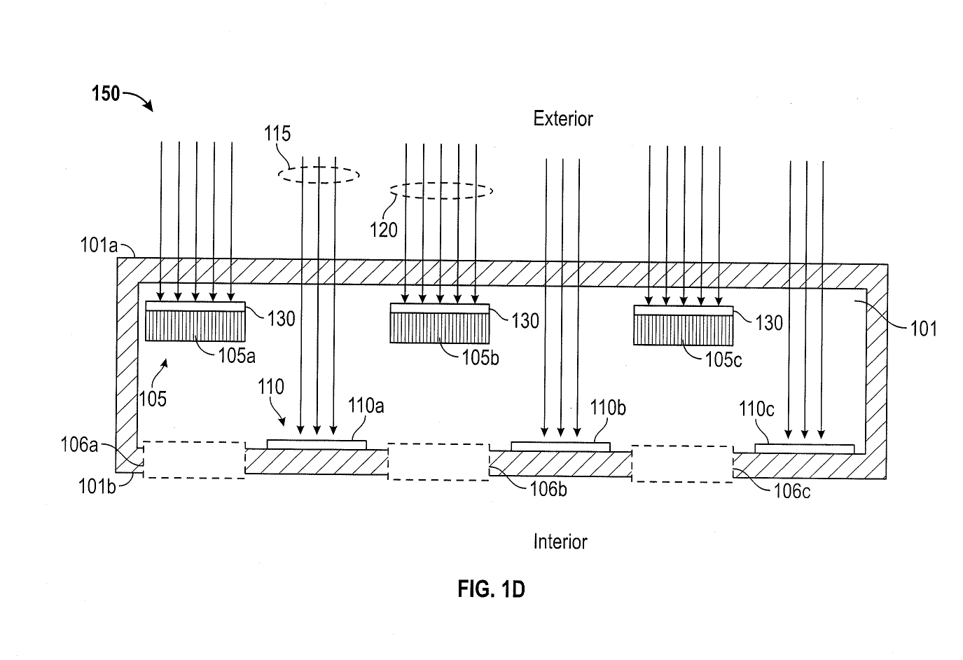

FIGS. 1A and 1B illustrate an implementation of a panel 100 including an array 105 of shutters, each shutter 105a, 105b and 105c configured to move laterally in a plane in which the shutter is aligned between an open state and a closed state. The panel 100 illustrated in FIGS. 1A and 1B includes a substrate 101 having a forward surface 101a that faces the ambient environment and receives ambient light and a rearward surface 101b that is opposite the forward surface and through which light exits the panel 100. A person having ordinary skill in the art will appreciate that the terms “forward” and “rearward” as used in referring to light collector surfaces herein do not indicate a particular absolute orientation, but instead are used to indicate a light collecting surface (“forward surface”) on which natural light is incident and a surface where a portion of the incident light received on the forward surface 101a can propagate out from (“rearward surface”). The panel 100 includes a plurality of apertures 106a, 106b, and 106c disposed closer to the rearward surface 101b of the panel 100 through which ambient light incident on the forward surface 101a of the panel 100 is transmitted out of the panel 100. The transmissivity of the plurality of apertures 106a-106c can be between approximately 80% and approximately 100%. Portions of the rearward surface 101b of the panel 100 (for example, area 125) that do not include an aperture can have a transmissivity that varies between approximately 0% and approximately 100%.

In the open state, the shutters 105a, 105b and 105c are in a first position such that they are not aligned with the plurality of apertures 106a-106c. FIG. 1A depicts the array 105 of shutters 105a-105c in the open state. In the open state, the panel 100 is configured to transmit a first portion of the ambient light incident on the forward surface of the panel 100 and block a second portion of the ambient light incident on the exterior portion of the panel 100. For example, as illustrated in FIG. 1A, a first radiation beam 120 (for example, light) that enters the panel 100 and is not incident on any of the shutters 105a, 105b and 105c in the array 105 is transmitted through the aperture 106b out of the rearward surface 101b of the panel 100. In the same configuration a portion of the ambient light, for example, a second radiation beam 115 (for example, light) that enters the panel 100 and is incident on any of the shutters 105a, 105b and 105c in the array 105 is blocked by the shutters 105a-105c and is not transmitted through the panel 100. Accordingly, the panel 100 has a transmissivity less than 100% in the open state. In various implementations, the transmissivity of the panel 100 can vary between approximately 30% and approximately 50% depending on the size, shape and density of the shutters 105a-105c and the apertures 106a-106c.

The amount of light transmitted through the panel 100 can be varied by moving the shutters 105a, 105b and 105c to a closed state. FIG. 1B depicts the array 105 of shutters 105a-105c in the closed state. In the closed state, the shutters 105a, 105b and 105c are moved laterally in a plane in which the shutters 105a-105c are aligned (for example, to the left) to a second position such that each shutter 105a-105c is aligned with a corresponding aperture 106a-106c. In various implementations, the plane in which the shutters 105a-105c are aligned can be parallel to the plane of the forward surface 101a or the rearward surface 101b or both. In the closed state, the first radiation beam 120 which was previously transmitted through the panel 100 is now incident on the shutter 105b and blocked from exiting through aperture 106b and the second radiation beam 115 which was previously incident on the shutter 105a is now incident on the area 125 of the rearward surface 101b of the panel 100 that does not include an aperture. Depending on the transmissivity of the area 125, the optical beam 115 can be blocked or partially/completely transmitted through the panel 100. In some implementations the shutters 105 can be configured to move between a “shut” and a full open position. In other implementations, the shutters 105 are configured to be positioned at one or more positions between a maximum open position and a minimum open position. Depending on the size, shape and density of the shutters 105a-105c and the apertures 106a-106c and the transmissivity of the portion of the rearward surface of the panel 100 that is devoid of apertures, the panel 100 has a transmissivity that can vary between approximately 0% and approximately 50% in the closed state.

In the implementations illustrated in FIGS. 1A and 1B, only the amount of light that is transmitted through the panel 100 is regulated. If the panel 100 illustrated in FIGS. 1A and 1B are configured for use as a window or a skylight, then the shutters 105a-105c function as mini/micro blinds that are integrated in the window or the skylight. Depending on the design of the shutters 105a-105c, the amount of light that is transmitted through the panel 100 can be controlled electrically.

In various implementations, the light that is blocked by the shutters 105a-105c can be used to generate PV power. FIGS. 1C and 1D illustrate an implementation of a PV power generating panel 150 including the panel 100 depicted in FIGS. 1A and 1B and an array 110 of PV devices 110a, 110b and 110c. In various implementations, the array 110 of PV devices 110a-110c may be disposed closer to the rearward surface 101b of the panel 150. For example, the array 110 of PV devices 110a-110c can be disposed on the portion (for example, area 125) of the rearward surface of the panel 150 that does not include an aperture. In the implementation illustrated in FIGS. 1C and 1D, the array 105 of shutters 105a-105c is disposed closer to the forward surface of the PV power generating panel 150 and the array 110 including PV devices 110a, 110b and 110c is disposed rearward of the array of shutters 105 closer to the rearward surface of the panel 150. In some implementations, each shutter 105a-105c can include a PV device 130 that can absorb ambient light and generate PV power.

FIG. 1C depicts the PV power generating panel 150 in the open state. In this configuration, the shutters 105a-105c are in a first position and are aligned with the array of PV devices 110a, 110b and 110c such that each shutter 105a, 105b and 105c in the array 105 overlaps partially or completely with a corresponding PV device 110a, 110b and 110c in the array 110 as illustrated in FIG. 1C. In this configuration, as described above with reference to FIG. 1A, the first radiation beam 120 enters the panel 150 and is not incident on any of the shutters 105a, 105b and 105c in the array 105, and propagates through the propagates through the interior portion of the panel 150 and passes out through aperture 106b. In the same configuration the portion of the ambient light represented by the second radiation beam 115 that was previously blocked by the shutter 105a and is now absorbed by the PV device 130 included in the shutter 105a and converted to electrical power.

FIG. 1D depicts the PV power generating panel 150 in the closed state. In this configuration, each of the shutters 105a-105c is moved laterally in a plane in which the shutter is aligned (for example, to the left) to a second position such that each shutter 105a-105c is aligned with a corresponding aperture 106a-106c. In other words, each shutter 105a-105c may be aligned with an aperture 106a-106c with respect to the direction of radiation (e.g., radiation beams 115 and 120) propagated through the panel 150. In various implementations, in the second position, each shutter 105a-105c may not overlap with a corresponding PV device 110a, 110b and 110c in the array 110 as illustrated in FIG. 1D. In other implementations, in the second position, each shutter 105a-105c may overlap with a corresponding PV device 110a, 110b and 110c in the array 110 to a lesser extent as compared to the extent of overlap in the first position. In the closed state, the optical beam 120 which was previously transmitted through the panel 150 is now absorbed by the PV device 130 included in the shutter 105b and converted to PV power. The second radiation beam 115 which was previously incident on the shutter 105a is now incident on the PV device 110a of the array 110 and converted to PV power.

In accordance with the discussion above, the amount of light transmitted through the panel 150 is reduced in the closed state as compared to the amount of light transmitted through the panel in the open state. In the closed state, or a partially closed state, more incident radiation reaches PV device 110. Consequently, in the closed state, the amount of power generated is increased as compared to the amount of PV power generated in the open state. In various implementations, the transmissivity of the panel 150 in the open state can vary between approximately 30% and approximately 50% depending on the size, shape and density of the shutters 105a-105c, the apertures 106a-106c, and the PV devices 110a-110c. Depending on the size, shape and density of the shutters 105a-105c, the apertures 106a-106c and the PV devices 110a-110c, the panel 150 has a transmissivity that can vary between approximately 0% and approximately 50% in the closed state.

The substrate 101 includes a transparent or transmissive material such as glass, plastic, polycarbonate, polyester or cyclo-olefin. In various implementations, the forward and rearward surfaces 101a and 101b of the substrate 101 can be parallel. In other implementations, the substrate 101 can be wedge shaped such that the forward and rearward surfaces 101a and 101b are inclined with respect to each other. The substrate 101 may be formed as a plate, sheet or film, and fabricated from a rigid or a semi-rigid material. In various implementations, portions of the substrate 101 may be formed from a flexible material. In some implementations, the panel 150 can include two transmissive substrates. A first transmissive substrate can include the shutters 105a-105c and a second substrate disposed rearward of the first substrate can include the PV devices 110a-110c. In various implementations, the two substrates may be separated by a gap. In various implementations, the substrate 101 can have a thickness such that the panels 100 and 150 have a thickness of about 0.5-8 inches.

The PV devices 110a-110c and 130 can convert radiation into electrical power. In various implementations, the PV devices 110a-110c and 130 can include solar cells. The PV devices 110a-110c and 130 can include a single or a multiple layer p-n junction and may be formed of silicon, amorphous silicon or other semiconductor materials such as cadmium telluride. In some implementations, PV devices 110a-110c and 130 can include photo-electrochemical cells. Polymer or nanotechnology may be used to fabricate the PV devices 110a-110c and 130. In various implementations, PV devices 110a-110c and 130 can include thin film photodiodes having several multispectrum layers, each multispectrum layer can have a thickness between approximately 1 μm to approximately 250 μm. The multispectrum layers can further include nanocrystals dispersed in polymers. Several multispectrum layers can be stacked to increase efficiency of the PV devices 110a-110c and 130.

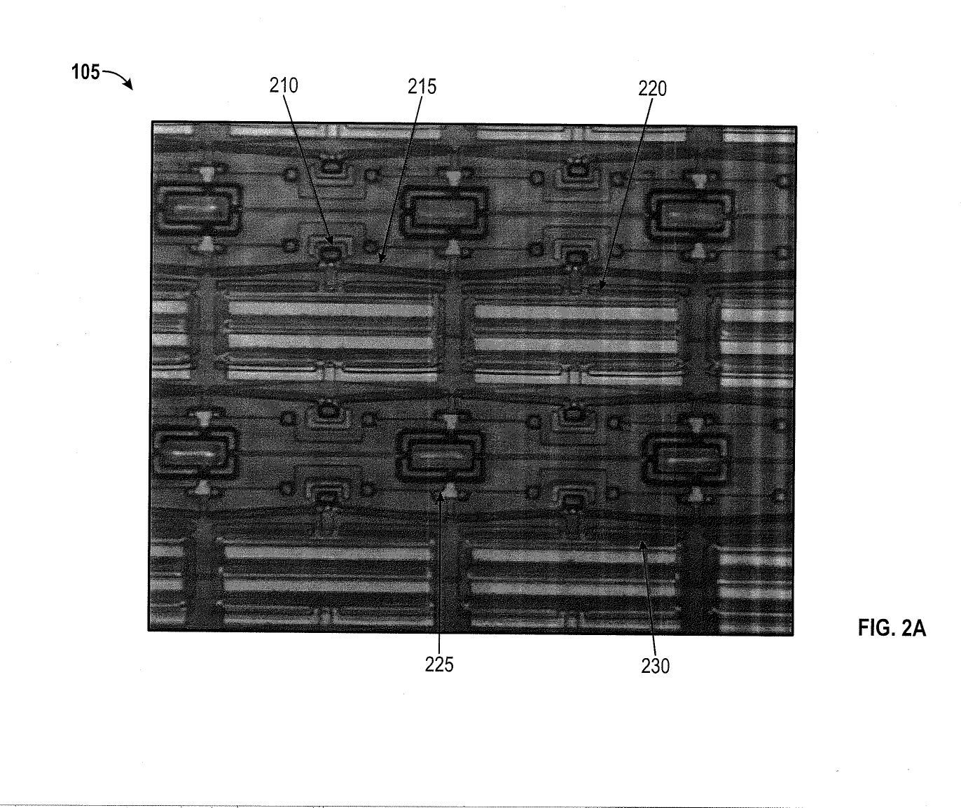

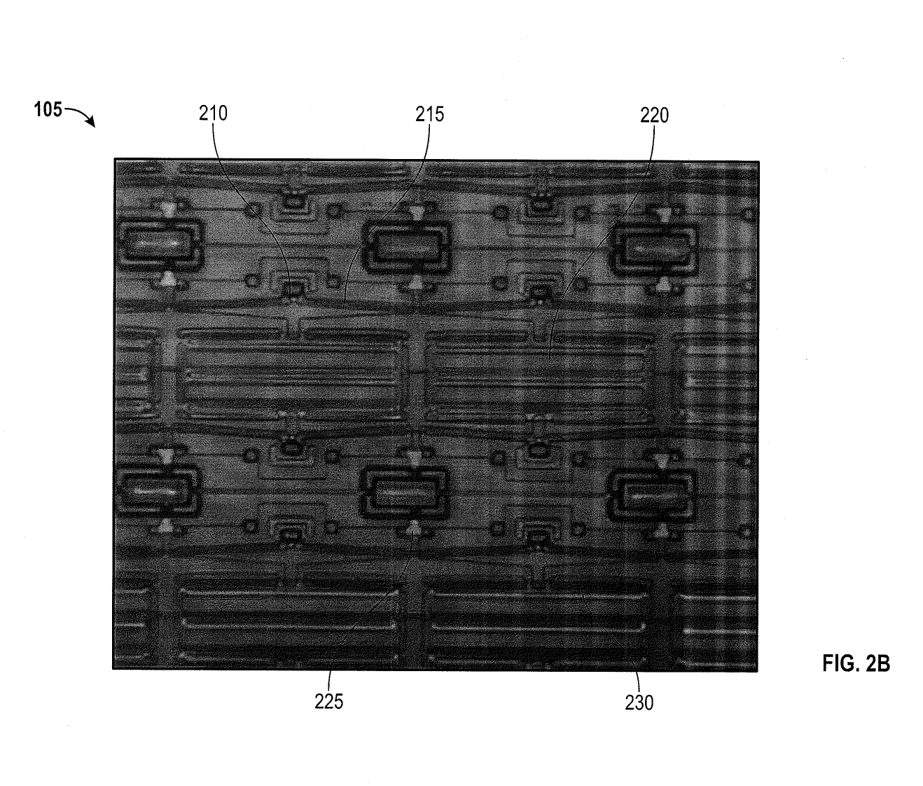

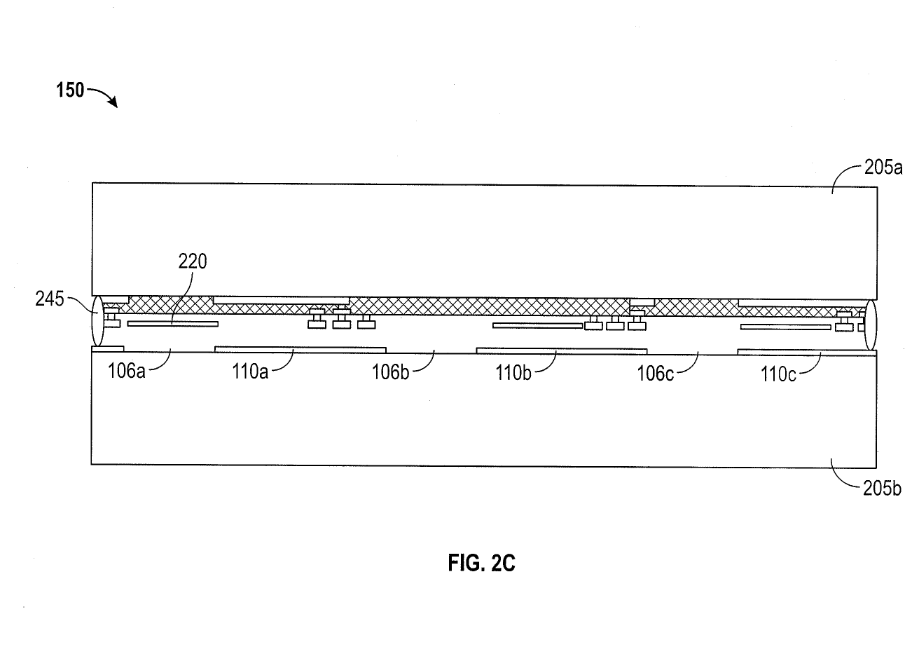

In various implementations, the shutters 105a-105c can include mechanical shutters that reflect or absorb ambient light. The mechanical shutters can be slidable laterally in the plane in which the shutters aligned or rotatable about an axis intersecting the shutter. For example, the shutters 105a-105c can include deformable mirror device (DMDs) which are rotatable or pivotable about an axis. An example of a slidable opto-mechanical shutter is described below with reference to FIGS. 2A-2C. The opto-mechanical shutters can be actuated (for example, moved horizontally, vertically, diagonally or rotated about an axis) by using electrostatic effect, piezo-electric effect, or mechanically. Although, the FIGS. 1A-1D show an opto-mechanical shutter, in various implementations, the shutters 105a-105c can utilize opto-electric, acousto-optic, interference or diffraction phenomenon to vary the transmissivity of ambient light. In some implementations the shutters 105a-105c can include liquid crystal material that can vary between a transmissive state and an absorptive/reflective state to vary the transmissivity of ambient light. Other shutters that are known to a person having ordinary skill in the in the art can also be used. Although FIGS. 1A-1D depict that all the shutters 105a-105c are simultaneously open or simultaneously closed, a person having ordinary skill in the art would realize that in some implementations each shutter 105a-105c can be individually controlled such that only some of the shutters is open while the rest are closed. This can be useful to further control the amount of light transmitted through the panel 100 and 150 and the amount of PV power generated by the panel 150. Additionally, although FIGS. 1A-1D and the description above disclose that the shutters 105a-105c are moved between a first position and a second position. A person having ordinary skill in the art would recognize that in various implementations, the position of the shutters 105a, 105b and 105c can be varied between the open state and the closed state such that the shutters 105a-105c occupy a variety of positions (for example, one or more positions) between the first and the second position. In such implementations, the amount of light transmitted through the panels 100 and 150 can be varied continuously, semi-continuously or discretely between a maximum amount and a minimum amount.

FIGS. 2A and 2B illustrate a plan view of an implementation of an array of microelectromechanical systems (MEMs) based shutters 220 that are electrostatically actuated to move laterally in a plane in which the shutters are aligned between an open state and a closed state. Each of the MEMs based shutter 220 depicted in FIGS. 2A and 2B can be individually driven by a pair electrostatic actuators to block and unblock light. One electrostatic actuator from the pair of electrostatic actuators is configured to close the shutter and another is configured to open the shutter. Each shutter 220 is suspended from support beam 230 which is anchored at a support beam anchor 225. In some implementations the support beam 230 acts as a mechanical spring and also as a first electrode of one of the actuators. A drive beam 215 anchored at a drive beam anchor 210 may act as a second electrode of one of the actuators. An electrical connection for activating the shutters may be provided through the drive beam anchor 210. In this implementation, the shutter 220 may be actuated by applying a potential difference between the support beam 230 (first electrode) and the drive beam 215 (second electrode). The applied potential difference generates an attractive force which pulls the support beam 230 toward the drive beam 215 resulting in the shutter 220 being pulled laterally. FIG. 2A depicts the array of MEMs based shutters 220 in the open state and FIG. 2B depicts the array of MEMs based shutters 220 in the closed state.

FIG. 2C illustrates a side view of an implementation of a PV power generating panel 150 including the MEMs based shutter 220 depicted in FIGS. 2A and 2B. The panel 150 illustrated in FIG. 2B includes a first transmissive substrate 205a including the array of shutters 220 and a second transmissive substrate 205b including the apertures 106a-106c and the PV devices 110a-110c. The first and the second transmissive substrates 205a and 205b are separated by a spacer 245. In various implementations, the shutter 220 can include the PV device 130 discussed above. In the PV power generating panel 150, the array of shutters 220 is disposed closer to the rearward surface of the first substrate 205a and the array of PV devices 110a-110c is disposed closer to (or on the) forward surface of the second substrate 205b. The array of shutters 220 can be fabricated on the rearward surface of the substrate 205a by using a variety of fabrication methods such as patterning, etching, lithography, chemical and physical vapor deposition techniques, etc. The array of PV devices 110a-110c can be fabricated on the forward surface of the substrate 205b by using a variety of fabrication methods such as patterning, etching, lithography, chemical and physical vapor deposition techniques, etc.

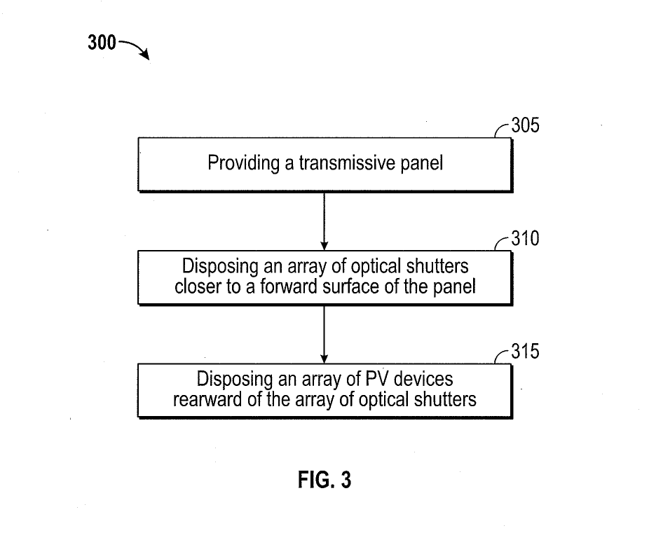

FIG. 3 is a flow chart 300 illustrating an example of a method of manufacturing an implementation of a power generating device including an array of shutters and PV devices. The method includes providing a transmissive panel as shown in block 305. The transmissive substrate can be similar to the substrates 101, 205a and 205b discussed above. The method further includes disposing an array of shutters closer to a forward surface of the panel as shown in block 310. The array of shutters can be similar to the shutters 105a-105c and 220 discussed above. The method also includes disposing an array of PV devices rearward of the array of shutters as shown in block 315. The array of shutters and the PV devices can be disposed using a variety of fabrication methods known to a person having ordinary skill in the art including but not limited to patterning, etching, lithography, chemical and physical vapor deposition techniques, etc.

The implementations described herein can include filters to reduce the amount of ultraviolet (UV) or infrared (IR) radiation that is transmitted through. The implementations described herein can additionally be configured to reduce color dispersion and image distortion; serve as thermal barrier and block solar radiation thereby aid in reducing heating and cooling costs; be designed to meet advanced building codes and standards; minimize fire hazard; supply better daylight as compared to conventional BIPV products; recycle indoor lighting energy; help in achieving “net zero building” by generating electric power, be cut into arbitrary shapes and sizes according to the building requirement and be aesthetically pleasing as conventional windows.

A wide variety of other variations are also possible. Films, layers, components, and/or elements may be added, removed, or rearranged. Additionally, processing operations may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A power generating and power saving device comprising:
a transmissive panel having a forward surface for receiving ambient light and a rearward surface opposite the forward surface;
an array of shutters disposed closer to the forward surface of the panel, each shutter including a layer of photovoltaic (PV) material disposed facing the forward surface of the panel, and each shutter in the array adapted to move between an open state and a closed state; and
an array of PV devices disposed rearward of the array of shutters,
wherein the array of shutters and the array of photovoltaic devices are structured in shape and/or size such that
in the open state a first portion of the received ambient light is transmitted through the rearward surface of the substrate and a second portion of the received ambient light is incident on the layer of PV material on the shutters, and
in the closed state a first portion of the received ambient light is incident on the layer of PV material on the shutters and a second portion of the received ambient light is incident on the array of PV devices.

2. The device of claim 1, wherein in the open state the first portion is between approximately 30% and approximately 50% of the received ambient light.

3. The device of claim 1, wherein in the open state the second portion is between approximately 10% and approximately 50% of the received ambient light.

4. The device of claim 1, wherein in the closed state the first portion is between approximately 5% and approximately 50% of the received ambient light.

5. The device of claim 1, wherein in the closed state a second portion is between approximately 30% and approximately 50% of the received ambient light.

6. The device of claim 1, wherein in the open state each shutter is aligned with a corresponding PV device from the array of PV devices such that less than 10% of the received ambient light is directly incident on the array of PV devices.

7. The device of claim 1, wherein in the closed state each shutter is offset with respect to a corresponding PV device from the array of PV devices such that the second portion of the received ambient light is directly incident on the PV devices.

8. The device of claim 1, wherein the panel includes a first transmissive substrate having a forward and a rearward surface, and wherein the array of shutters is disposed closer to the rearward surface of the first substrate.

9. The device of claim 1, wherein the panel includes a second transmissive substrate having a forward and a rearward surface, and wherein the array of PV devices is disposed over the forward surface of the second substrate facing the array of shutters.

10. The device of claim 1, wherein some of the array of shutters include a mechanical shutter that is configured to move laterally in a plane parallel to the forward surface of the panel between the open state and the closed state.

11. The device of claim 10, wherein the mechanical shutter can be moved between the open state and the closed state by one or more electro-static actuators.

12. The device of claim 10, wherein the mechanical shutter is suspended from one or more support structures.

13. The device of claim 12, wherein the support structure is configured as a mechanical spring.

14. The device of claim 12, wherein the support structure is configured as an electrode of an electro-static actuator that is adapted to slide the mechanical shutter.

15. The device of claim 1, wherein the array of PV devices includes a thin film photovoltaic cell.

16. The device of claim 1, configured as a window.

17. The device of claim 1, configured as a skylight.

18. A power generating and power saving device comprising:
a transmissive panel having a forward surface for receiving ambient light and a rearward surface opposite the forward surface;
a plurality of means for blocking light disposed closer to the forward surface of the panel, each light blocking means including a layer of photovoltaic (PV) material disposed facing the forward surface of the panel, and each light blocking means adapted to move between an open state and a closed state; and
an array of PV devices disposed rearward of the plurality of light blocking means,
wherein the plurality of light blocking means and the array of photovoltaic devices are structured in shape and/or size such that
in the open state a first portion of the received ambient light is transmitted through the rearward surface of the panel and a second portion of the received ambient light is incident on the layer of PV material on the light blocking means, and
in the closed state a first portion of the received ambient light is transmitted through the rearward surface of the panel and a second portion of the received ambient light is incident on the array of photovoltaic devices.

19. The device of claim 18, wherein the plurality of light blocking means includes a mechanical shutter.

20. The device of claim 18, wherein the plurality of light blocking means is configured to move laterally in a plane parallel to the forward surface of the panel between the open state and the closed state.

21. The device of claim 20, wherein the plurality of light blocking means can be moved between the open state and the closed state by one or more electro-static actuators.

22. A method of manufacturing a power generating device, the method comprising:
providing a transmissive panel having a forward surface for receiving ambient light and a rearward surface opposite the forward surface;
disposing an array of shutters disposed closer to the forward surface of the panel, each shutter including a layer of PV material disposed facing the forward surface of the panel, and each shutter in the array adapted to move between an open state and a closed state; and
disposing an array of PV devices disposed rearward of the array of shutters,
wherein the array of shutters and the array of PV devices are structured in shape and/or size such that
in the open state a first portion of the received ambient light is transmitted through the rearward surface of the panel and a second portion of the received ambient light is incident on the layer of PV material on the shutters, and
in the closed state a first portion of the received ambient light is transmitted through the rearward surface of the panel and a second portion of the received ambient light is incident on the array of PV devices.

23. The method of claim 22, wherein some of the array of shutters include a mechanical shutter that is configured to move laterally in a plane parallel to the forward surface of the panel between the open state and the closed state.

24. The method of claim 23, further comprising suspending the mechanical shutter from one or more support structures.

25. The method claim 24, further comprising providing an electro-static actuator including the support structure, the electro-static actuator adapted to move the mechanical shutter between the open state and the closed state.
